(19) United States
(12) Patent Application Publication
(10) Pub. No.: US 2018/0076167 A1
(43) Pub. Date: Mar. 15, 2018

(54) METALLIC RIBBON FOR POWER MODULE PACKAGING

(71) Applicant: Wire Technology Co., LTD., Taichung City (TW)

(72) Inventors: Chien-Hsun CHUANG, Taichung City (TW); Hsing-Hua TSAI, Taichung City (TW); Shang-Chih WANG, Taichung City (TW)

(21) Appl. No.: 15/588,557

(22) Filed: May 5, 2017

(30) Foreign Application Priority Data
Sep. 13, 2016 (TW) 105129747

(51) Int. Cl. H01L 23/00

(52) U.S. Cl. CPC H01L 24/45; H01L 2224/45164; H01L 24/05; H01L 24/32; H01L 2224/04042; H01L 2224/05582; H01L 2224/05624; H01L 2224/05644; H01L 2224/05655; H01L 2224/45624; H01L 2224/45644; H01L 2224/45664; H01L 2924/0132; H01L 2924/01079; H01L 2924/01046; H01L 2224/45014; H01L 2224/32225; H01L 2224/45016; H01L 2224/48227; H01L 2224/48091; H01L 2224/48105; H01L 2224/73265; H01L 2924/01047; H01L 2224/45139; H01L 24/48

(57) ABSTRACT

A metallic ribbon for power module packaging is described. The metallic ribbon has a rectangular, oval or oblong cross section. The composition of the metallic ribbon is silver-palladium alloy containing 0.2 to 6 wt % Pd. The metallic ribbon has a thickness of 10 μm to 500 μm. The width of the metallic ribbon is 2 to 100 times its thickness. The metallic ribbon includes a plurality of grains. The average grain size of the grains observed in the transverse cross section is 2 μm to 10 μm. The metallic ribbon has a plurality of twin grains observed in the transverse cross section, and the number of twin grains observed in the transverse cross section accounts for at least 5% of the total number of grains observed in the transverse cross section.

### CROSS REFERENCE TO RELATED APPLICATIONS

This Application claims priority of Taiwan Patent Application No. 105129747 filed on Sep. 13, 2016, the entirety of which are incorporated by reference herein.

### BACKGROUND

The present disclosure relates to a metallic ribbon for power module packaging, and it particularly relates to a silver-alloy metallic ribbon for power module packaging.

The inverter of an electric vehicle motor control unit is the key component to convert electrical energy to kinetic energy, and the power electrical module has great effect on the energy conversion efficiency. The voltage to current ratio (voltage/current) of power module for vehicle motor reaches 600V/450 A, which is much higher than other power modules and ICs of consuming electronic products, and power modules should pass the reliability tests in Automotive Electronics Council Q101 (AEC-Q101). Therefore, power modules require high standard materials and packaging technologies. Power module packaging should provide interconnections between bonding pads on the chip and bonding pads on the substrate. The conventional materials of the interconnections is aluminum (Al) wire, however, since the power modules of insulated gate bipolar transistors (IGBT) should be able to withstand high current, the diameter of the aluminum (Al) wires should be large. For example, Infineon, Mitsubishi Electric Corporation, and Siemens, which are main international manufacturers of IGBT modules for vehicles, use aluminum wire with a large diameter (about 15 mil or 380 μm) as the interconnection for power chips, which are different from the wire (with a diameter of about 1 mil) generally used in IC and LED packaging. Since the IGBT has a gate, an emitter bonding pad deposited on the gate, and an insulating SiO₂ layer disposed between the gate and the emitter bonding pad, the large-diameter aluminum wire might crack the SiO₂ layer due to the high bonding forces, and result in a short circuit between the emitter and the gate. In addition, since the melting point of the aluminum wire is low, the bonding points might melt when being applied to high power modules. Furthermore, aluminum wire oxidizes easily, which impacts the reliability of the power modules. Additionally, aluminum wire has high electromigration, which can damage the power modules.

Aluminum ribbon is used as interconnection in more advanced power modules to increase the bonding strength of the interconnection. However, the aluminum ribbon also has the disadvantage of having a low melting point, which causes the bonding points to melt. The aluminum ribbon also has the disadvantages of being easily oxidized and having high electromigration.

Copper (Cu) wire and copper ribbon are also candidates for power module packaging. However, since both copper wire and copper ribbon can easily oxidize and erode, the reliability of these products is a concern. The problems of oxidization and erosion cannot be completely solved even if precious metals (e.g., gold, palladium, or platinum) are coated on the surfaces of the copper wires or copper ribbons. Worse still, since the hardness of copper wires and copper ribbons is too high, the chips of the power modules can easily crack during the bonding process. In addition, it is hard to form intermetallic compounds between the copper wires and the aluminum pads of the chips, resulting in a low bonding strength of the bonding points, or even worse, resulting in faulty welding. When the ultrasonic bonding process is performed, since the substrate is not heated, it is even harder to form the intermetallic compounds, and the problem of faulty welding becomes worse. Therefore, using copper wire or copper ribbon as the material of the interconnection is very challenging. To overcome the problems caused by the hardness of the copper wires and copper ribbons, composites including copper wires covered by aluminum layers are also considered as candidates for materials of interconnections, however, it does not improve the operation of the interconnections, and reliability remains controversial.

Furthermore, gold (Au) wire or gold ribbon with small dimensions are also used in a few power module packaging processes. However, gold wire and gold ribbon is very expensive, and the gold wire or gold ribbon with small dimensions might not be able to withstand the operation of high power chips. In addition, during power module reliability tests or high-temperature operations, a lot of intermetallic compounds are formed between the aluminum pads of the chips and the gold wires or gold ribbons, thus cracking the bonding interface, decreasing the electrical conductivity and thermal conductivity, and eroding the interface.

In summary, the existing interconnections for power module packaging do not fully meet the requirements, and some improvements are desired.

### SUMMARY

In some embodiments, the present disclosure relates to a metallic ribbon for power module packaging. The metallic ribbon has a rectangular, oval or oblong cross section. The composition of the metallic ribbon is silver-palladium alloy containing 0.2 to 6 wt % Pd. The metallic ribbon has a thickness of 10 μm to 500 μm. The width of the metallic ribbon is 2 to 100 times its thickness. The metallic ribbon includes a plurality of grains. The average grain size of the grains observed in the transverse cross section is 2 μm to 10 μm. The metallic ribbon has a plurality of twin grains observed in the transverse cross section, and the number of twin grains observed in the transverse cross section accounts for at least 5% of the total number of grains observed in the transverse cross section.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to 1C illustrate perspective drawings of the metallic ribbons for power module packaging in accordance with some embodiments of the present disclosure.

FIG. 2A to 2C illustrate the metallography of the transverse cross section of the metallic ribbons for power module packaging in accordance with some embodiments of the present disclosure.

FIG. 3A to 3C illustrate the metallography of the transverse cross section of the metallic ribbons for power module packaging in accordance with some embodiments of the present disclosure.

FIG. 4 illustrates the 3-D metallography of the metallic ribbons for power module packaging in accordance with some embodiments of the present disclosure.

FIGS. 5 to 6 illustrate cross-sectional views of the power modules using the metallic ribbons for power module packaging in accordance with some embodiments of the present disclosure.

FIG. 7 illustrates the surface topography of the cracked bonding pads after the wire bonding process in accordance with some comparative embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To solve the problems of conventional materials of power module packaging interconnections, the present disclosure discloses metallic ribbon for power module packaging which is made of silver alloys (i.e., silver is the major component) containing palladium. Silver has high electrical conductivity and thermal conductivity, and the palladium in the silver alloy can improve the strength, the oxidation resistance, and the moisture corrosion resistance of the ribbons. In addition, the palladium can also inhibit silver migration. Since the palladium has a low diffusion rate, it can prevent brittle intermetallic compounds from forming too much between the metallic ribbons and the aluminum bonding pads. However, if too much palladium is added in the silver alloy, it might increase the hardness, the brittleness, and the resistance of the silver alloy ribbon. Therefore, the amount of palladium added should be within a proper range (e.g., 0.2 wt %-6 wt %).

In reliability tests, it was found that the metallic ribbon for power module packaging in the present disclosure forms enough intermetallic compounds on its interface with the bonding pad of the power IC chip to provide good bonding qualities. In addition, during the reliability tests or during the operation, the power packaging product using the metallic ribbon in the present disclosure does not have the faulty welding problem of copper wires and copper ribbons caused by the difficult formation of the intermetallic compounds. Furthermore, during reliability tests or during operation, the metallic ribbon for power module packaging of the present disclosure has low growth rate of intermetallic compounds, and thus does not have the disadvantage of excess formation of intermetallic compounds as found in gold wire and gold ribbon. In addition, since the hardness of the metallic ribbon for power module packaging in the present disclosure is lower than that of copper wires and copper ribbons, it does not crack the power chip, thus improving the workability of the ultrasonic wire bonding process.

Compared with various silver alloy wires (long, thin cylinders with a substantially round cross section), the silver-palladium alloy ribbons for power module packaging in the present disclosure have a larger bonding area with the bonding pad of the power chip in the ultrasonic wire bonding process. On the other hand, large force should be applied to the silver or silver alloy wires (long, thin cylinders) to obtain plastic deformation of the wires to increase the bonding area. The silver alloy ribbons for power module packaging in the present disclosure have better workability of the ultrasonic wire bonding process than conventional silver alloy wires. In addition, compared with the conventional silver alloy wires, the power packaging products using the silver alloy ribbons for power module packaging in the present disclosure also have better bonding strength and reliability.

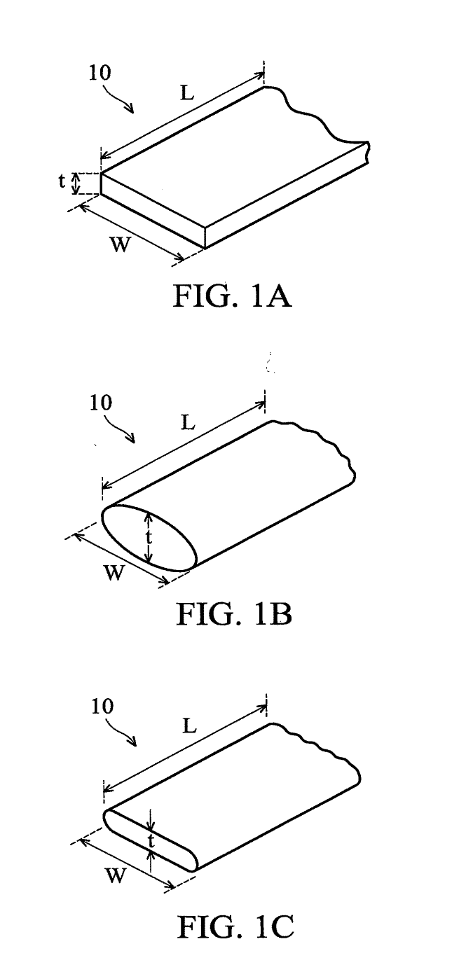

In some embodiments, as shown in FIG. 1A to 1C, the metallic ribbon 10 for power module packaging is a substantial cylinder having a thickness t, and a width w. For example, the thickness t is 10 μm to 500 μm, and the width w is 2 to 200 times the thickness t, but the width w is not greater than 5 mm in most cases. Generally, the metallic ribbon 10 can have a total length of 100 m to 5 km, and can be cut to the proper length L (e.g., 5 mm to 100 mm) in the packaging process, but it is not used to limit the present disclosure.

Furthermore, when pure silver or silver alloy wires are used, the diameter of the wires should be greater than 50 μm to meet the requirements of the high power packaging (e.g., for electric vehicles). However, the bonding pads can crack easily in the ultrasonic wire bonding process when the silver or silver alloy wires have a large diameter (e.g., greater than 50 μm). To avoid the above problem, the average grain sizes of the silver or silver alloy large-diameter wires should be larger than 10 μm, resulting in insufficient strength of the silver or silver alloy wires, higher annealing temperature, and longer annealing time in the annealing process. In addition, it further impacts the production efficiency, and raises the concern of surface oxidization. By contrast, when the silver-palladium alloy ribbon in the present disclosure (e.g., a silver alloy containing 0.02 wt % to 6 wt % palladium) having a thickness of 10 μm to 500 μm, and a width 2 to 200 times the thickness (though the width w is not larger than 5 mm) is used in the ultrasonic bonding process, even if the average grain size is 2 μm to 10 μm, the bonding pad does not crack. In other words, the metallic ribbon for power module packaging in the present disclosure can meet the dimension requirements (e.g., a thickness of 10 μm to 500 μm, and a width of 2 to 200 times the thickness but not larger than 5 mm) of the high power packaging without sacrificing its strength. In addition, the metallic ribbon for power module packaging in the present disclosure has a higher production efficiency than wires with coarse grains.

Additionally, more than 5% (e.g., 5% to 60%) of the grains of the metallic ribbon for power module packaging in the present disclosure are annealing twin grains, thus having the advantages of high electrical conductivity, high thermal conductivity, improved oxidation resistance, and improved resistance to chloride corrosion. The grain boundaries of the twin grains can effectively inhibit the electromigration. In addition, the twin grain boundaries with low energies can pin other high angle grain boundaries around the twin grain to make the high angle grain boundaries hard to move, and thus the grain growth is inhibited, and the heat affected zone is hardly formed. Furthermore, the crystallization orientations of the twin grain and the grain enclosing the twin grain are different, and thus strengthening the metallic ribbons by inhibiting the dislocation from moving. Therefore, the tensile strength and the elongation of the metallic ribbon for power module packaging in the present disclosure are not lower than the conventional power chip interconnections with fine grains. The above advantages can result in good performance of the module using the metallic ribbon for power module packaging in the present disclosure in the reliability tests.

As follows, some metallic ribbons for power module packaging of some embodiments in the present disclosure are described with the figures.

As shown in FIG. 1A to 1C, “the transverse cross section” refers to a cross section perpendicular to the rolling direction or the drawing direction of the ribbon in the rolling process or drawing process, it includes the maximum width w and the maximum thickness t of the ribbon. It should be noted that appropriate steps, such as cutting, polishing, grinding, and etching, can be performed for the metallurgical test to obtain a better position for examination, and it is not necessary to use the whole cross section of the ribbon for examination.

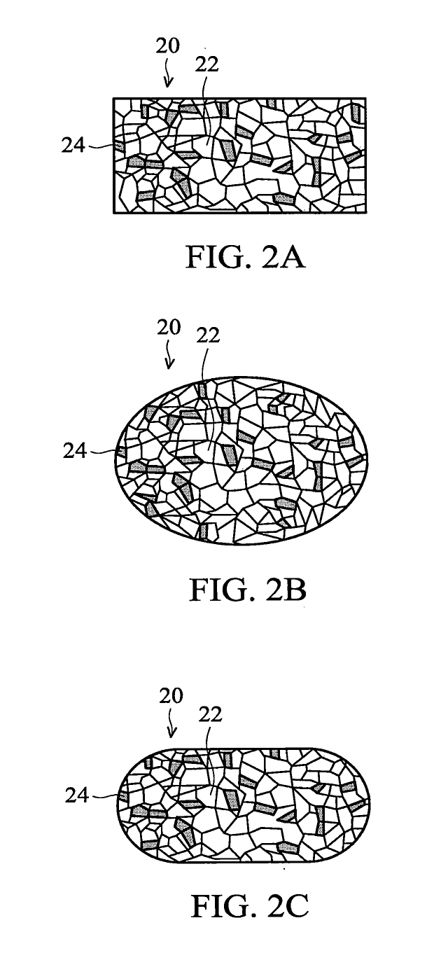

Then, refer to FIG. 2A to 2C, the metallography of the transverse cross section of the metallic ribbon 20 for power module packaging is illustrated. The shape of the transverse cross section can be rectangular (as shown in FIG. 2A), oval (as shown in FIG. 2B), or oblong (as shown in FIG. 2C). As shown in the figures, the metallic ribbon 20 for power module packaging includes a plurality of grains 22 with an average grain size of 2 μm to 10 μm. The number of grains with the twin structures 24 accounts for at least 5% (e.g., 5% to 60%) of the total number of grains 22 observed in the transverse cross section.

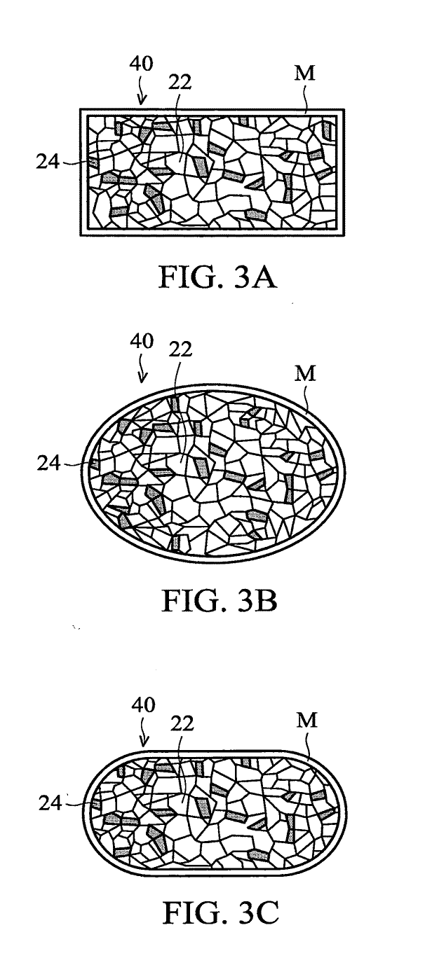

In some embodiments, one or more layers of metal thin film M with a total thickness of 0.01 μm to 1 μm can be used to cover the metallic ribbon 20 for power module packaging of the above-mentioned embodiments to form the metallic ribbon 40 for power module packaging, as shown in FIG. 3A to 3C. The shape of the transverse cross section of the metallic ribbon 40 can be rectangular, oval, or oblong. The metal thin film M can include substantially pure aluminum, substantially pure gold, substantially pure palladium, gold-palladium alloy, or a combination thereof. The metal thin film M can be formed using proper plating processes (e.g., electroplating, sputtering, or vacuum evaporation). The metal thin film M can inhibit the moisture corrosion and the ion migration of the silver alloy material, and decrease the intermetallic compound formation rate on the interface after the bonding process.

The average grain size in the transverse cross section, the proportion of the number of grains with twin structures to the total number of grains in the transverse cross section of the above-mentioned ribbons, and the hardness of the transverse cross section of the ribbon are measured by the following methods.

The grains in the transverse cross section of the ribbon can be observed by an appropriate cutting process and metallographic procedures. A grind wheel cutting method, a band saw cutting method, a water jet cutting method, a laser cutting method, a focus ion beam (FIB) method, or another similar method may optionally be used to cut the ribbon. The specimens are prepared in accordance with ASTM E3 or similar specifications. Since the transverse cross sections of the ribbon substantially have the same area, at least three transverse cross sections can be randomly taken according to how many specimens is needed. After cutting, general metallographic procedures, such as polishing, grinding, and proper etching can be performed to show the grain structure. The grain structure can be observed using instruments, such as an optical microscope (OM), a scanning electron microscope (SEM), or focus ion beam (FIB). The magnification should be chosen to obtain at least one hundred grains within the observed field. The inner portion and the outer portion of the transverse cross section of the cut ribbon should be observed.

The average grain size of the transverse cross section of the ribbon can be calculated according to ASTM E112 or similar specifications.

The hardness of the transverse cross section of the ribbon can be measured according to ASTM E92 or similar specifications.

The twin grains are observed by directly counting the number of grains with twin structures in the metallographic picture of the transverse cross section obtained according to methods such as ASTM E3 or ASTM E112. The proportion of the grains with twin structures in the transverse cross section to all the grains in the transverse cross section can be obtained by counting the total number of grains and the number of grains with twin structures in the metallographic picture.

For example, the metallic ribbon having dimensions and microstructures in accordance with the present disclosure can be formed by performing a proper rolling or drawing process, and/or an annealing process, and/or a cutting process on silver-palladium alloy wires containing 0.02 wt % to 6 wt % palladium. In addition, a metal layer M (e.g., substantially pure aluminum, substantially pure gold, substantially pure palladium, or gold-palladium alloy) with a total thickness of 0.01 μm to 1 μm may optionally be formed on the surface of the metallic ribbon using the proper methods (e.g., electroplating, sputtering, or vacuum evaporation).

To describe further the advantages of the metallic ribbons for power module packaging in the present disclosure, some experimental data are incorporated as follows.

### Preparative Example 1

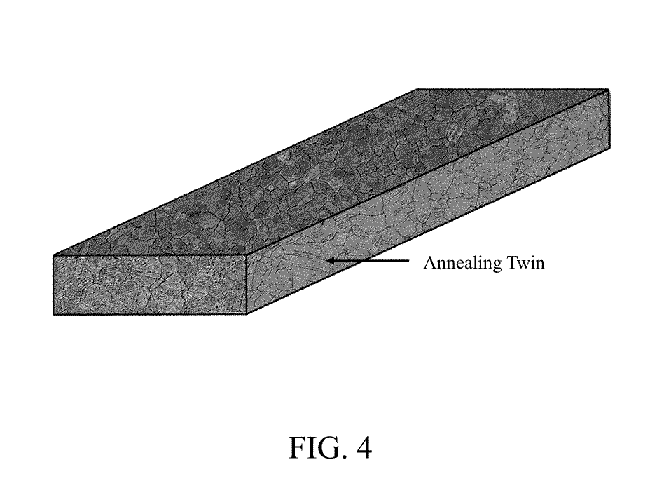

To manufacture the metallic ribbons 20 having rectangular transverse cross sections of the following example 1, at first, Ag-2 wt % Pd, Ag-4 wt % Pd, and Ag-6 wt % Pd wires with a diameter of 240 μm are respectively rolled once to form metallic ribbons having a width of 1.5 mm and a thickness of 100 μm. Then, the metallic ribbons are annealed at 600° C. for 60 minutes. For example, the grain structure of the metallic ribbon with the composition of Ag-4 wt % Pd is shown in FIG. 4. In addition, the average grain size and the proportion of the grains with the twin structures in the transverse cross section for the metallic ribbons after the annealing process are shown in Table 1.

TABLE 1

| | transverse cross section | |
|---|---|---|
| Composition of the | average grain size | proportion of the grains with |
| metallic ribbon | (μm) | the twin structures (%) |
| Ag-2 wt % Pd | 8.5 | 32 |
| Ag-4 wt % Pd | 7.9 | 28 |
| Ag-6 wt % Pd | 6.5 | 25 |

### Preparative Example 2

To manufacture the metallic ribbons 20 having oval or oblong transverse cross sections of the following example 2, at first, Ag-4 wt % Pd wires with diameter of 504 μm are drawn with an oval drawing dye or an oblong drawing dye to form metallic ribbons having a width of 2 mm and a maximum thickness of 100 μm. Then, the metallic ribbons are annealed at 600° C. for 60 minutes. The grain structures of metallic ribbons 20 having oval or oblong transverse cross sections are similar to the grain structures of metallic ribbons 20 having rectangular transverse cross sections as shown in FIG. 4. The average grain sizes of the above metallic ribbons 20 having oval or oblong transverse cross sections are 8.2 and 8.5 μm respectively. The proportions of the number of grains with twin structures to the total number of grains in the transverse cross section of the metallic ribbons 20 having oval and oblong transverse cross sections are 24% and 21% respectively.

### Preparative Example 3

To form the metallic ribbon 40 having rectangular transverse cross section of the following example 3, a gold (Au) layer M with a thickness of 1 μm is formed on the surface of the Ag-4 wt % Pd metallic ribbon 20 of manufacturing example 1 using the electroplating method.

### Example 1

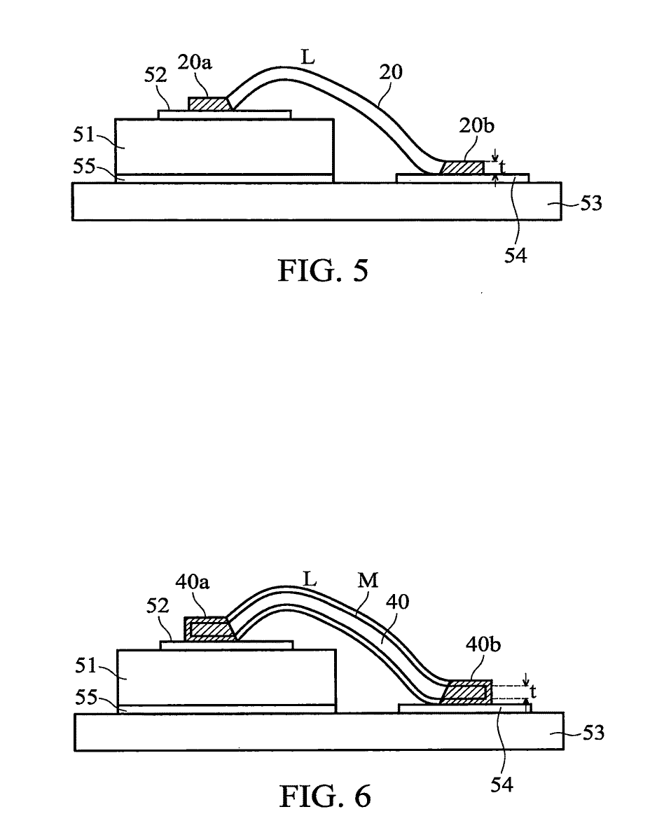

As shown in FIG. 5, one end of the metallic ribbon 20 having a width of 1.5 mm and a thickness of 100 μm was bonded to the aluminum bonding pad 52 coated with nickel/gold of the power chip 51 using the ultrasonic method, and thus a first bonding point 20a was formed. Then, the metallic ribbon 20 was drawn to the copper bonding pad 54 of the direct copper bonding (DCB) alumina ceramic substrate 53. Then, the second bonding point 20b was formed using the ultrasonic method, and thus the metallic ribbon 20 was bonded to the copper bonding pad 54 of the direct copper bonding (DCB) alumina ceramic substrate 53. Then, the excess metallic ribbon 20 was cut off near the second bonding point 20b and the interconnection was kept intact. The remaining metallic ribbon 20 had the proper length L. In addition, solder material 55 could be used to bond the power chip 51 and the alumina ceramic substrate 53.

In example 1, the Ag-2 wt % Pd, Ag-4 wt % Pd, and Ag-6 wt % Pd metallic ribbons 20 having rectangular transverse cross sections had better UPH (units per hour) in the ultrasonic bonding process than the Ag-2 wt % Pd, Ag-4 wt % Pd, and Ag-6 wt % Pd silver-palladium alloy wires. The results of the reliability tests of the power module packaging products using the metallic ribbons 20 are shown in Table 2. The power module packaging products using the metallic ribbons 20 were able to withstand the pressure cooker test (PCT) for more than 128 hours, and withstand the highly accelerated stress test (HAST) for more than 128 hours.

TABLE 2

| TEST ITEM | TEST CONDITION | Results |
|---|---|---|
| 1.Precondition Test | Bake(125 +5-0° C., 24 hours) | Passed |
| | Temperature and humidity test(30° C., | |
| | 60% RH, 192 hours) | |
| | Reflow: (260 +0/−5° C., 3 times) | |
| 2.Pressure Cooker Test; PCT | Ta = 121° C., 100% RH, 2 atm, 96 hours | Passed |
| 3.Temperature Cycling Test; TCT | Ta = −65° C.~150° C. (air to air), | Passed |
| | 15 minutes/chamber | |
| | 1000 cycles | |
| 4.Temperature & Humidity Test; THT | Ta = 85° C., 85% RH, no bias voltage | Passed |
| | 1000 hours | |
| 5.High-Temperature Storage Test; | Ta = 150° C. | Passed |
| HTST | 1000 hours | |
| 6.Low Temperature Storage Test; | Ta = −40° C. | Passed |
| LTST | 1000 hours | |
| 7.Solderability test | Steam aging: 93° C., 8 hours, | Passed |
| | Soldering dip condition: 245° C., | |
| | 5 seconds | |
| 8.Highly Accelerated Stress Test; | Ta = 148° C., 90% RH, 3.6 Voltage bias | Passed |
| HAST | 96 hours | |
| 9.Thermal shock Test; TST | Ta = −65° C.~150° C., 5 minutes/chamber | Passed |
| | 1000 cycles | |

### Example 2

As shown in FIG. 5, one end of the metallic ribbon 20 (with the composition of Ag-4 wt % Pd, and with the oval or oblong transverse cross sections) having a width of 2 mm and a maximum thickness of 100 μm was bonded to the aluminum bonding pad 52 coated with nickel/gold of the power chip 51 using the ultrasonic method, and thus a first bonding point 20a was formed. Then, the metallic ribbon 20 was drawn to the copper bonding pad 54 of the direct copper bonding (DCB) alumina ceramic substrate 53. Then, the second bonding point 20b was formed using the ultrasonic method, and thus the metallic ribbon 20 was bonded to the copper bonding pad 54 of the direct copper bonding (DCB) alumina ceramic substrate 53. Then, the excess metallic ribbon 20 was cut off near the second bonding point 20b and the interconnection was kept intact. The remaining metallic ribbon 20 had the proper length L. In addition, solder material 55 could be used to bond the power chip 51 and the alumina ceramic substrate 53.

In example 2, the Ag-4 wt % Pd metallic ribbons 20 having oval or oblong transverse cross sections both had better UPH (units per hour) in the ultrasonic bonding process than the Ag-4 wt % Pd metallic ribbon 20 having rectangular transverse cross section in example 1, and also had better UPH than the Ag-0.5 wt % Pd, Ag-4 wt % Pd, and Ag-6 wt % Pd silver alloy wires. In addition, the power module packaging products using the metallic ribbons 20 having oval or oblong transverse cross sections in example 2 also passed the reliability tests as outlined in Table 2.

### Example 3

The difference between example 3 and example 1 is that the outer portions of the metallic ribbons in example 3 further include a layer of metal thin film.

As shown in FIG. 6, the metallic ribbon 40 (with the composition of Ag-4 wt % Pd, and with the rectangular transverse cross section) having a width of 1.5 mm and a thickness of 100 μm was coated with a gold layer M. The metallic ribbon 40 was bonded to the aluminum bonding pad 52 coated with nickel/gold of the power chip 51 and the copper bonding pad 54 of the direct copper bonding (DCB) alumina ceramic substrate 53 by forming the third bonding point 40a and fourth bonding point 40b using methods similar to those in example 1. In example 3, the UPH of the metallic ribbon 40 in the ultrasonic bonding process was higher than that of the Ag-4 wt % Pd silver alloy wire coated with gold. In addition, the power module packaging products using the metallic ribbons 40 in example 3 also passed the reliability tests as outlined in Table 2.

### Example 4

The difference between example 4 and example 2 is that the outer portions of the metallic ribbons in example 4 further include a layer of metal thin film.

As shown in FIG. 6, the metallic ribbon 40 (with the composition of Ag-4 wt % Pd, and with the oval or oblong transverse cross sections) having a width of 1.5 mm and a maximum thickness of 100 μm was coated with a gold layer M. The metallic ribbon 40 was bonded to the aluminum bonding pad 52 coated with nickel/gold of the power chip 51 and the copper bonding pad 54 of the direct copper bonding (DCB) alumina ceramic substrate 53 by forming the third bonding point 40a and fourth bonding point 40b using methods similar to those in example 2. In example 4, the UPH of the metallic ribbon 40 in the ultrasonic bonding process was higher than the UPH of the Ag-4 wt % Pd silver alloy wire coated with gold, which was 78%. In addition, the power module packaging products using the metallic ribbons 40 in example 4 also passed the reliability tests as outlined in Table 2.

### Comparative Example 1

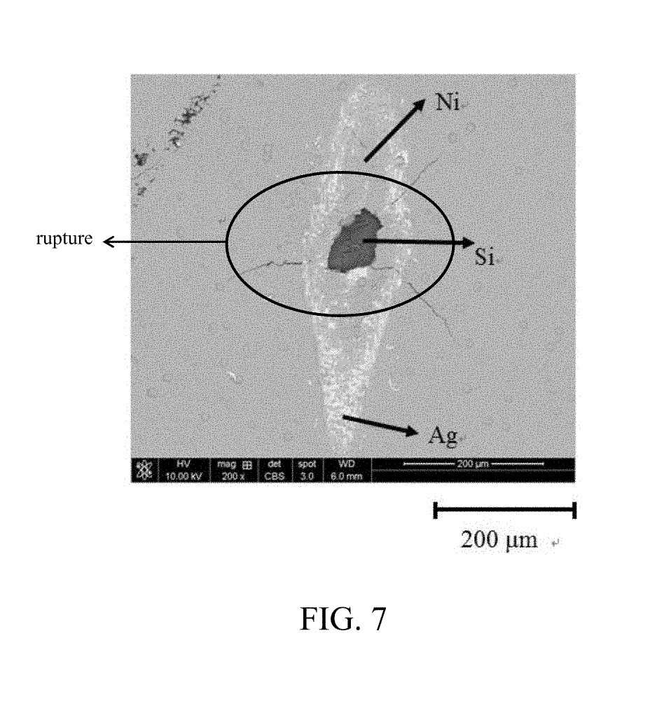

To further illustrate the advantages of the metallic ribbons of the present disclosure over the wires, in comparative example 1, the Ag-4 wt % Pd silver alloy wire having a diameter of 200 μm and an average grain size of 8.3 μm was bonded to a bonding pad coated with nickel/gold on a Si chip using the ultrasonic wire bonding process. Since the hardness of the fine grain wire was as high as 71 Hv, as shown in FIG. 7, the bonding pad was cracked after the wire bonding process.

Although the disclosure has been described by way of example and in terms of the preferred embodiments, they are not used to limit the present disclosure. Not all advantages of the present disclosure are described in detail herein. Those skilled in the art may design or modify other processes and structures without departing from the spirit and scope of the present disclosure. Therefore, the scope of protection is better determined by the claims.

What is claimed is:

1. A metallic ribbon for power module packaging, wherein:
the metallic ribbon has a rectangular, oval or oblong cross section;
a composition of the metallic ribbon is a silver-palladium alloy comprising 0.2 to 6 wt % palladium;
the metallic ribbon has a thickness of 10 μm to 500 μm;
a width of the metallic ribbon is 2 to 100 times the thickness;
the metallic ribbon comprises a plurality of grains, an average grain size of grains observed in a transverse cross section of the metallic ribbon is 2 μm to 10 μm; and
the metallic ribbon has a plurality of twin grains observed in the transverse cross section of the metallic ribbon, and a number of the twin grains observed in the transverse cross section accounts for at least 5% of a total number of the grains observed in the transverse cross section.

2. The metallic ribbon for power module packaging of claim 1, wherein a hardness of the metallic ribbon is 40 Hv to 70 Hv.

3. The metallic ribbon for power module packaging of claim 1, wherein the width of the metallic ribbon is not greater than 5 mm.

4. The metallic ribbon for power module packaging of claim 1, wherein a surface of the metallic ribbon is covered by one or more metal layers, wherein a composition of the one or more metal layers comprises substantially pure aluminum, substantially pure gold, substantially pure palladium, or gold-palladium alloy.

5. The metallic ribbon for power module packaging of claim 4, wherein a hardness of the metallic ribbon is 40 Hv to 70 Hv.

6. The metallic ribbon for power module packaging of claim 4, wherein the width of the metallic ribbon is not greater than 5 mm.

7. The metallic ribbon for power module packaging of claim 4, wherein the one or more metal layers has a thickness of 0.01 μm to 1 μm.
